(19) United States
(12) Patent Application Publication
(10) Pub. No.: US 2026/0223504 A1
(43) Pub. Date: Jul. 30, 2026

(54) FLEXIBLE ELECTRONIC DEVICE

(71) Applicant: INNOLUX CORPORATION, Miao-Li County (TW)

(72) Inventors: Kuan-Hung KUO, Miao-Li County (TW); Chiung-Chieh KUO, Miao-Li County (TW); Tsung-Yu HUANG, Miao-Li County (TW); Feng-Yu LIN, Miao-Li County (TW); Ying-Chi CHENG, Miao-Li County (TW); Kuan-Wen TSENG, Miao-Li County (TW)

(21) Appl. No.: 19/441,492

(22) Filed: Jan. 6, 2026

(30) Foreign Application Priority Data
Jan. 24, 2025 (CN) 202510113049.6

(51) Int. Cl. H10H 29/24

(52) U.S. Cl. CPC H10H 29/24

(57) ABSTRACT

A flexible electronic device including a first flexible layer, an electronic component layer, a polarization layer, an anti-reflective layer, a support layer, a first adhesive layer and a second adhesive layer. The electronic component layer is disposed on the first flexible layer. The polarization layer is disposed at one side of the electronic component layer away from the first flexible layer. The anti-reflective layer is disposed at one side of the polarization layer away from the electronic component layer. The support layer is disposed at one side of the first flexible layer away from the electronic component layer. The first adhesive layer is disposed between the first flexible layer and the support layer, and the second adhesive layer is disposed between the anti-reflective layer and the polarization layer. The thickness of the first adhesive layer is greater than the thickness of the second adhesive layer.

### CROSS REFERENCE TO RELATED APPLICATIONS

This Non-provisional application claims priority under 35 U.S.C. § 119(a) on Patent Application No(s). 202510113049.6 filed in China on Jan. 24, 2025, the entire contents of which are hereby incorporated by reference.

### BACKGROUND

### Technology Field

This disclosure relates to an electronic device and, in particular, to a flexible electronic device.

### Description of Related Art

In recent years, the technology of flexible electronic device has matured and is applied in various electronic products, such as display devices, mobile phones, or the likes. However, when the flexible electronic devices are bent, they can generate obvious ambient light reflection at the bending portion. This reflection can degrade visual quality in, for example, the display device. Therefore, it is desired to provide a solution to reduce the reflectivity of flexible electronic device while ensuring structural flexibility and/or reliability.

### SUMMARY

This disclosure provides a flexible electronic device that can reduce the reflectivity thereof so as to improve the ambient contrast ratio as well as ensuring structural flexibility and/or reliability thereof.

A flexible electronic device of this disclosure includes a first flexible layer, an electronic component layer, a polarization layer, an anti-reflective layer, a support layer, a first adhesive layer and a second adhesive layer. The electronic component layer is disposed on the first flexible layer. The polarization layer is disposed at one side of the electronic component layer away from the first flexible layer. The anti-reflective layer is disposed at one side of the polarization layer away from the electronic component layer. The support layer is disposed at one side of the first flexible layer away from the electronic component layer. The first adhesive layer is disposed between the first flexible layer and the support layer. The second adhesive layer is disposed between the anti-reflective layer and the polarization layer. The thickness of the first adhesive layer is greater than the thickness of the second adhesive layer.

Another flexible electronic device of this disclosure includes a first flexible layer, a second flexible layer, an electronic component layer, a color filter layer, an anti-reflective layer, a first support layer, a second support layer, a first adhesive layer and a second adhesive layer. The second flexible layer is disposed opposite to the first flexible layer. The electronic component layer is disposed between the first flexible layer and the second flexible layer. The color filter layer is disposed between the second flexible layer and the electronic component layer. The anti-reflective layer is disposed at one side of the second flexible layer away from the first flexible layer. The first support layer is disposed at one side of the first flexible layer away from the second flexible layer. The second support layer is disposed at one side of the anti-reflective layer away from the second flexible layer. The first adhesive layer is disposed between the first support layer and the first flexible layer. The second adhesive layer is disposed between the anti-reflective layer and the second flexible layer. The thickness of the first adhesive layer is greater than the thickness of the second adhesive layer.

Another flexible electronic device of this disclosure includes a plurality of tile portions, a first support layer and a first adhesive layer. The tile portions are tiled and disposed on the first support layer through the first adhesive layer. Each of the tile portions includes a first flexible layer, a second flexible layer, an electronic component layer, a color filter layer, an anti-reflective layer, a second support layer, and a second adhesive layer. The first support layer is disposed at one side of the first flexible layer, and the first adhesive layer is disposed between the first support layer and the first flexible layer. The second flexible layer is disposed opposite to the first flexible layer. The electronic component layer is disposed between the first flexible layer and the second flexible layer. The color filter layer is disposed between the second flexible layer and the electronic component layer. The anti-reflective layer is disposed at one side of the second flexible layer away from the first flexible layer. The second support layer is disposed at one side of the anti-reflective layer away from the second flexible layer. The second adhesive layer is disposed between the anti-reflective layer and the second flexible layer. The thickness of the first adhesive layer is greater than the thickness of the second adhesive layer.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic sectional view showing a flexible electronic device according to a first embodiment of this disclosure;

FIG. 2 is a schematic sectional view showing a flexible electronic device according to a second embodiment of this disclosure;

FIG. 3 is a schematic sectional view showing a flexible electronic device according to a third embodiment of this disclosure;

FIGS. 4A to 4C are schematic partial sectional views showing different aspects of a tiled flexible electronic device of this disclosure;

FIG. 5 is a schematic partial sectional view showing a tiled flexible electronic device of this disclosure;

FIG. 6 is a schematic sectional view showing a flexible electronic device according to a fourth embodiment of this disclosure;

FIG. 7 is a schematic sectional view showing a flexible electronic device according to a fifth embodiment of this disclosure;

FIG. 8 is a schematic sectional view showing a flexible electronic device according to a sixth embodiment of this disclosure;

FIG. 9 is a schematic sectional view showing a flexible electronic device according to a seventh embodiment of this disclosure; and

FIG. 10 is a schematic sectional view showing a flexible electronic device according to an eighth embodiment of this disclosure.

### DETAILED DESCRIPTION OF THE DISCLOSURE

It should be understood that the following description provides different embodiments for implementing different aspects of some embodiments of the present disclosure.

To be noted, without departing from the spirit of the present disclosure, the features in several different embodiments may be replaced, reorganized, or mixed to complete other embodiments.

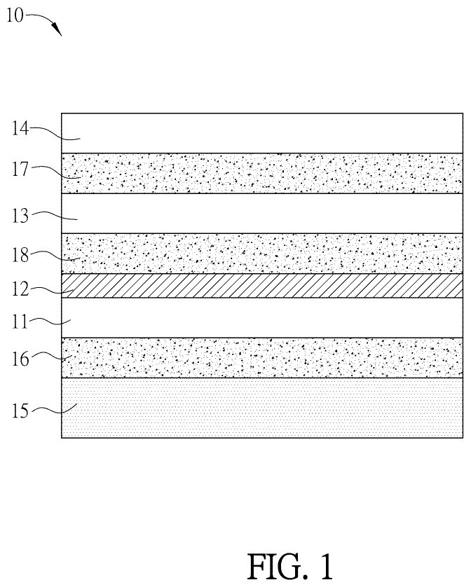

As shown in FIG. 1, the flexible electronic device 10 of this embodiment includes a first flexible layer 11, an electronic component layer 12, a polarization layer 13, an anti-reflective layer 14, a support layer 15, a first adhesive layer 16, and a second adhesive layer 17. In addition, the flexible electronic device 10 can further include a third adhesive layer 18.

The first flexible layer 11 can be, for example, a film, a layer or a substrate with flexibility or resilience. The material thereof may include, for example but not limited to, transparent or opaque organic and/or inorganic materials, which are flexible or resilient. The organic materials may include polyimide (PI), fiber-reinforced plastic (FRP), polyethylene terephthalate (PET), cycloolefin polymers (COP), or other known suitable materials, or combinations of the above materials, but this disclosure is not limited thereto. The inorganic materials may include glass, quartz, sapphire or ceramics, but this disclosure is not limited thereto. In this embodiment, the material of the first flexible layer 11 is polyimide, for example, so that the first flexible layer 11 is a flexible substrate.

The electronic component layer 12 is disposed on the first flexible layer 11. In this embodiment, the electronic component layer 12 includes, for example, a plurality of electronic components and a plurality of circuit components. The electronic components can be, for example, micro LEDs, so that the electronic component layer 12 includes a plurality of micro LEDs. The circuit components include, for example, different passive components and/or active components, such as resistors, capacitors, inductors, diodes, thin-film transistors (TFTs), MOSFETs, CMOS transistors, BJTs, LDMOS transistors, PMOS transistors, or other types of transistors. In this case, the circuit components can be used to control and/or drive the electronic components. For example, the circuit layer including a plurality of electronic components can be used to control and/or drive the micro LEDs (electronic components) to emit light, thereby achieving the image display effect.

The polarization layer 13 is disposed at one side of the electronic component layer 12 away from the first flexible layer 11. In this embodiment, the polarization layer 13 may be, for example, a circular polarizer, which may be disposed on the surface of the electronic component layer 12 away from the first flexible layer 11 through the third adhesive layer 18. For example, an adhesive material may be applied to the surface of the electronic component layer 12 away from the first flexible layer 11. The adhesive material may include a thermosetting material, a light-curing material, or other suitable adhesive materials, such as pressure-sensitive adhesive (PSA), optical clear adhesive (OCA), or optical clear resin (OCR), and this disclosure is not limited thereto. The polarization layer 13 is then disposed on the adhesive material. Finally, the adhesive material can be cured by heating or irradiation, thereby forming the third adhesive layer 18 between the electronic component layer 12 and the polarization layer 13. The polarization layer 13 can effectively reduce the intensity of reflected ambient light, thereby improving the ambient contrast ratio.

The anti-reflective layer 14 is disposed at one side of the polarization layer 13 away from the electronic component layer 12, and the second adhesive layer 17 is disposed between the anti-reflective layer 14 and the polarization layer 13. In this embodiment, the anti-reflective layer 14 can be, for example, an anti-reflective film, and the polarization layer 13 can be, for example, a circular polarizer. The anti-reflective layer 14 can be disposed on the surface of the electronic component layer 12 away from the first flexible layer 11 through the second adhesive layer 17. For example, an adhesive material can be coated on the surface of the polarization layer 13 away from the electronic component layer 12. The adhesive material can be, for example, a thermosetting material, a light-curing material, or other suitable adhesive materials, such as PSA, OCA, or OCR, and this disclosure is not limited thereto. The anti-reflective layer 14 is then disposed on the adhesive material. Finally, the adhesive material can be cured by heating or irradiation to form the second adhesive layer 17 between the anti-reflective layer 14 and the polarization layer 13. In another embodiment, the anti-reflective layer 14 and the second adhesive layer 17 may be independently manufactured and integrated as one component. For example, the anti-reflective layer 14 and the second adhesive layer 17 may be stacked together, and two release films may be provided on two sides of the stacked structure of the anti-reflective layer 14 and the second adhesive layer 17 for protection. During the manufacturing process, the release films must be removed in advance, and then one side of the second adhesive layer 17 is directly disposed on the polarization layer 13.

In this embodiment, the anti-reflective layer 14 can be, for example, a multilayer structure including alternately stacked high refractivity materials and low refractivity materials. For example, the multilayer structure may be formed by alternately stacking at least one high refractivity sublayer and at least one low refractivity sublayer. Therefore, the ambient light can pass through the anti-reflective layer 14 before entering the polarization layer 13, thereby reducing reflections of the ambient light at the interface between the polarization layer 13 and the air. The material of the low refractivity material (the material of the low refractivity sublayer) can be, for example, silicon oxide (SiOx), and the material of the high refractivity material (the material of the high refractivity sublayer) can be, for example, silicon nitride (SiNx), niobium oxide (Nb₂O), or the likes. This disclosure is not limited thereto.

The support layer 15 is disposed at one side of the first flexible layer 11 away from the electronic component layer 12, and the thickness of the support layer 15 is greater than that of the first flexible layer 11. In this embodiment, the support layer 15 may be, for example, a flexible protection film, a molding film, a supporting film, a flexible substrate, or the likes, and the material thereof may be, for example, a transparent or opaque organic or inorganic material, such as polyethylene terephthalate (PET), or other known suitable materials, or combinations thereof. This disclosure is not limited thereto. The support layer 15 may be disposed on the surface of the first flexible layer 11 away from the electronic component layer 12 through the first adhesive layer 16. For example, the support layer 15 can be placed on a work platform or in a mold. Then, the adhesive material is then coated on the upper surface of the support layer 15. The adhesive material can be, for example, a thermosetting material, alight-curing material, or other suitable adhesive materials, such as PSA, OCA, or OCR, and this disclosure is not limited thereto. Afterwards, the first flexible layer 11 is placed on the adhesive material. Finally, the adhesive material can be cured by heating or irradiation to form the first adhesive layer 16 between the first flexible layer 11 and the support layer 15. The thickness of the first adhesive layer 16 can be greater than or equal to the thickness of the third adhesive layer 18. In this case, the support layer 15 can provide protection and/or support functions for the entire structure of the flexible electronic device 10.

In addition to utilizing the aforementioned configuration of the polarization layer 13 and the anti-reflective layer 14 to reduce reflectivity and improve ambient contrast ratio, this embodiment also simultaneously ensures the flexibility and reliability of the flexible electronic device 10 by controlling the thickness of each layer. In this embodiment, the thickness of the first adhesive layer 16 is greater than the thickness of the second adhesive layer 17, and the thickness of the first adhesive layer 16 is greater than or equal to the thickness of the third adhesive layer 18. For example, the thickness of the first flexible layer 11 is between 1 μm and 100 μm, the thickness of the anti-reflective layer 14 is between 1 μm and 200 μm, the thickness of the support layer 15 is between 25 μm and 300 μm, the thickness of the first adhesive layer 16 is between 1 μm and 500 μm, the thickness of the second adhesive layer 17 is between 1 μm and 100 μm, and the thickness of the third adhesive layer 18 is between 1 μm and 500 μm.

As mentioned above, the corresponding relationship between stress and strain of each layer inside the flexible electronic device 10, when it is bent, for example, to a specified curvature radius Ro, can be simulated and calculated. The organized values are shown in Table 1 below.

TABLE 1

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| 3.584E−6 | 0.603E−6 | 78.6 | 1.301E−3 | −1.476E−3 | 0.175E−3 | 33/67 |

Referring to Table 1, the maximum stress represents the maximum stress value (in MPa) of each layer. For example, the maximum stress value of the electronic component layer 12 is 3.584E-6 MPa, and the maximum stress value of the first flexible layer 11 is 0.603E-6 MPa. The neutral axis ratio represents the proportion of the partial layers of the internal structure of the flexible electronic device 10 having strain values within a specific range of a given threshold value in the entire internal structure of the flexible electronic device 10. For example, if the neutral axis ratio is 78.6%, and the specific range is 1%, it means that the part of the internal structure of the flexible electronic device 10 having the strain values within the range of (the given threshold value×1.005) and (the given threshold value×0.995) is equal to 78.6% of all layers of the internal structure of the flexible electronic device 10. The specific range can be between 0.1% and 1%. The range of the internal structure of the flexible electronic device 10 having strain value within a specific range of a given threshold can be defined as the neutral axis region. That is, the strain values of the partial layers within this range approach zero. In other words, the neutral axis ratio represents the percentage of the device's total thickness where the bending-induced strain is minimal, for instance, within ±1% of the peak bending-induced strain is minimal, for instance, within ±1% of the peak strain. A higher ratio indicates a larger low-strain region, which contributes to better flexibility and reliability. The strain value of end surface represents the strain values at the topmost (upper end surface) and the bottommost (lower end surface) of all layers of the entire internal structure of the flexible electronic device 10. For example, the strain value at the upper end surface is 1.301E-3, and the strain value at the lower end surface is −1.476E-3. The strain difference represents the difference (in absolute value) of the above two strain values at the upper end surface and the lower end surface. For example, the strain difference is 0.175E-3. The deviation distance ratio of the electronic component layer 12 represents the ratio of the distances between the electronic component layer 12 and two end surfaces (lower end surface and upper end surface) of the neutral axis region. For example, if the deviation distance ratio of the electronic component layer 12 is 33/67, the electronic component layer 12 is closer to the lower end surface of the neutral axis region.

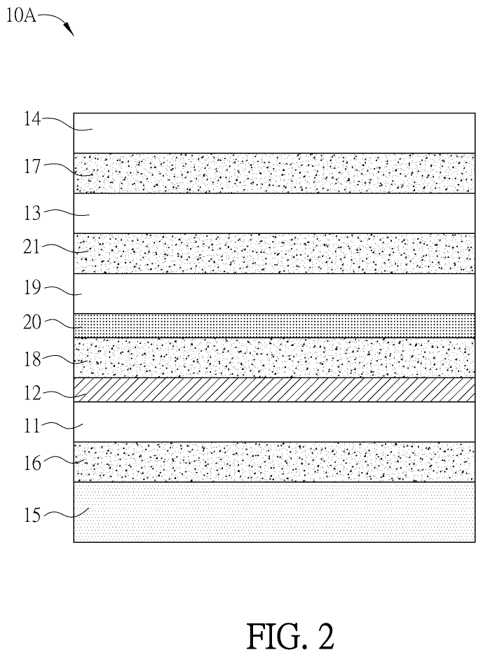

As shown in FIG. 2, compared with the previous embodiment of FIG. 1, the flexible electronic device 10A further includes a second flexible layer 19, a color filter layer 20, and a fourth adhesive layer 21. In this embodiment, the second flexible layer 19 is disposed between the polarization layer 13 and the electronic component layer 12, the color filter layer 20 is disposed between the second flexible layer 19 and the electronic component layer 12, and the third adhesive layer 18 is disposed between the color filter layer 20 and the electronic component layer 12. The material and property of the second flexible layer 19 can refer to those of the first flexible layer 11 described above, so the detailed description thereof will be omitted here. To be noted, when the flexible electronic device 10A is, for example, a display device, the transparency of the second flexible layer 19 with respect to visible light can be greater than that of the first flexible layer 11. In addition, the material and property of the fourth adhesive layer 21 can refer to those of the first adhesive layer 16 described above, so the detailed description thereof will be omitted here.

The color filter layer 20 may include a plurality of color filter units, such as a red filter unit, a blue filter unit, and a green filter unit. Correspondingly, the electronic component layer 12 may include, for example, a plurality of red micro LEDs, blue micro LEDs, and green micro LEDs. The red filter unit is correspondingly disposed above the red micro LED, the blue filter unit is correspondingly disposed above the blue micro LED, and the green filter unit is correspondingly disposed above the green micro LED.

In this embodiment, the thickness of the first adhesive layer 16 is greater than that of the second adhesive layer 17, and the thickness of the first adhesive layer 16 is greater than or equal to that of the third adhesive layer 18. For example, the thickness of the first flexible layer 11 is between 1 μm and 100 μm, the thickness of the anti-reflective layer 14 is between 1 μm and 200 μm, the thickness of the support layer 15 is between 25 μm and 300 μm, the thickness of the first adhesive layer 16 is between 1 μm and 500 μm, the thickness of the second adhesive layer 17 is between 1 μm and 100 μm, the thickness of the third adhesive layer 18 is between 1 μm and 50 μm, and the thickness of the fourth adhesive layer 21 is between 1 μm and 500 μm.

As mentioned above, the corresponding relationship between stress and strain of each layer inside the flexible electronic device 10A, when it is bent, for example, to a specified curvature radius Ro, can be simulated and calculated. The organized values are shown in Table 2 below.

TABLE 2

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| −0.002E−3 | 2.939E−3 | 90.6 | 1.398E−3 | −1.322E−3 | 0.076E−3 | 65/35 |

Referring to Table 2, in the flexible electronic device 10A of this embodiment, the maximum stress in the electronic component layer 12 is −0.002E-3 MPa, the maximum stress in the first flexible layer 11 is 2.939E-3 MPa, the neutral axis ratio is 90.6%, the strain value at the upper end surface is 1.398E-3, the strain value at the lower end surface is −1.322E-3, the strain difference is 0.076E-3, and the deviation distance ratio of the electronic component layer 12 is 65/35. In this case, the electronic component layer 12 is closer to the upper end surface of the neutral axis region.

The detailed description of other features of the electronic device 10A can refer to the previous embodiment, and will be omitted here.

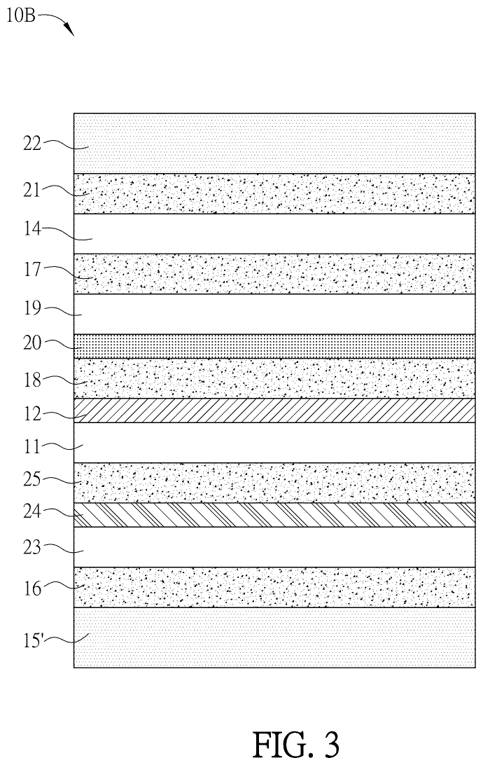

FIG. 3 is a schematic sectional view showing a flexible electronic device 10B according to a third embodiment of this disclosure. To be noted, unlike the previous embodiment, the flexible electronic device 10B of this embodiment further is not configured with the polarization layer 13. However, in other embodiments, the flexible electronic device 10B may be configured with the polarization layer, and this disclosure is not limited thereto.

As shown in FIG. 3, the flexible electronic device 10B includes a first flexible layer 11, an electronic component layer 12, an anti-reflective layer 14, a first support layer 15′, a first adhesive layer 16, a second adhesive layer 17, a third adhesive layer 18, a second flexible layer 19, a color filter layer 20, a fourth adhesive layer 21, a second support layer 22, a third flexible layer 23, a circuit layer 24, and a fifth adhesive layer 25. Furthermore, the flexible electronic device 10B of this embodiment can be, for example, a tiled flexible electronic device, but this disclosure is not limited thereto.

In this embodiment, the second flexible layer 19 is disposed opposite to the first flexible layer 11. The electronic component layer 12 is disposed between the first flexible layer 11 and the second flexible layer 19, and the electronic component layer 12 can be, for example, directly formed on one surface of the first flexible layer 11 close to the second flexible layer 19. The anti-reflective layer 14 is disposed at one side of the second flexible layer 19 away from the first flexible layer 11, and the anti-reflective layer 14 can be, for example, disposed on one surface of the second flexible layer 19 away from the first flexible layer 11 through the second adhesive layer 17. The first support layer 15′ is disposed at one side of the first flexible layer 11 away from the second flexible layer 19. The first adhesive layer 16 is disposed between the first support layer 15′ and the first flexible layer 11. The second adhesive layer 17 is disposed between the anti-reflective layer 14 and the second flexible layer 19. For example, the second adhesive layer 17 can be formed on the second flexible layer 19, and then the anti-reflective layer 14 is provided on the second adhesive layer 17. The color filter layer 20 is disposed between the second flexible layer 19 and the electronic component layer 12, and the color filter layer 20 can be disposed on the electronic component layer 12 through the third adhesive layer 18. The second support layer 22 is disposed at one side of the anti-reflective layer 14 away from the second flexible layer 19, and the second support layer 22 can be disposed on the anti-reflective layer 14 through the fourth adhesive layer 21. The third flexible layer 23 is disposed between the first flexible layer 11 and the first support layer 15′, and the third flexible layer 23 can be disposed on the first support layer 15′ through the first adhesive layer 16. The circuit layer 24 is disposed at one side of the third flexible layer 23 close to the first flexible layer 11. For example, the circuit layer 24 can be formed on the surface of the third flexible layer 23 close to the first flexible layer 11. In addition, the circuit layer 24 can be disposed under the first flexible layer 11 through the fifth adhesive layer 25.

As mentioned above, the thickness of the first adhesive layer 16 is greater than that of the second adhesive layer 17, and the thickness of the first adhesive layer 16 is greater than or equal to that of the third adhesive layer 18. With respect to visible light, the transparency of the second flexible layer 19 is greater than that of the first flexible layer 11. In this embodiment, the materials and properties of the first flexible layer 11, the electronic component layer 12, the anti-reflective layer 14, the first adhesive layer 16, the second adhesive layer 17, the third adhesive layer 18, the second flexible layer 19, the color filter layer 20, and the fourth adhesive layer 21 can refer to the same elements in the aforementioned embodiments, so the detailed descriptions thereof will be omitted here. In addition, the materials and properties of the first supporting layer 15′ and the second supporting layer 22 can refer to the support layer 15 of the aforementioned embodiments. To be noted, for example, when the flexible electronic device 10B of this embodiment is used as a display device, the material of the first supporting layer 15′ can include a transparent or opaque material, while the material of the second supporting layer 22 can include a transparent material. The material and property of the third flexible layer 23 can refer to that of the first flexible layer 11 of the aforementioned embodiment, and the material and property of the fifth adhesive layer 25 can refer to that of the first adhesive layer 16 of the aforementioned embodiment. The detailed descriptions thereof will be omitted here.

Moreover, the electronic component layer 12 is electrically connected to the circuit layer 24, and thus the control signals and/or driving power can be transmitted to the electronic component layer 12 through the circuit layer 24 for driving the electronic components of the electronic component layer 12. The circuit layer 24 may include one or more metal layers and one or more insulating layers stacked in an alternating manner. Specifically, the flexible electronic device 10B of this embodiment may be, for example, a tiled flexible electronic device, which includes a plurality of tile portions. Each of the tile portions may include, for example, a first flexible layer 11 and a multilayer structure disposed on the first flexible layer 11. For example, the multilayer structure can include an electronic component layer 12, a third adhesive layer 18, a color filter layer 20, a second flexible layer 19, a second adhesive layer 17, an anti-reflective layer 14, a fourth adhesive layer 21, and a second support layer 22, which are stacked on the first flexible layer 11. The plurality of tile portions may be tiled and disposed on a large-sized base structure, which may include, for example, a first support layer 15′, a first adhesive layer 16, a third flexible layer 23, and a circuit layer 24. For example, a large-sized first support layer 15′ can be placed in a tiling mold, and then an adhesive material (first adhesive layer 16) is coated on the first support layer 15′. The third flexible layer 23 formed with the circuit layer 24 is then placed on the adhesive material, so that the third flexible layer 23 is located between the circuit layer 24 and the first support layer 15′. Afterwards, the adhesive material can be cured to form the first adhesive layer 16. Then, multiple tile portions are placed on the circuit layer 24 through the fifth adhesive layer 25 to form a tiled flexible electronic device (flexible electronic device 10B).

To be noted, the electronic component layer 12 and the circuit layer 24 can be electrically connected by any suitable means, such as flexible circuit elements, side circuits, through-holes, or the likes as illustrated below.

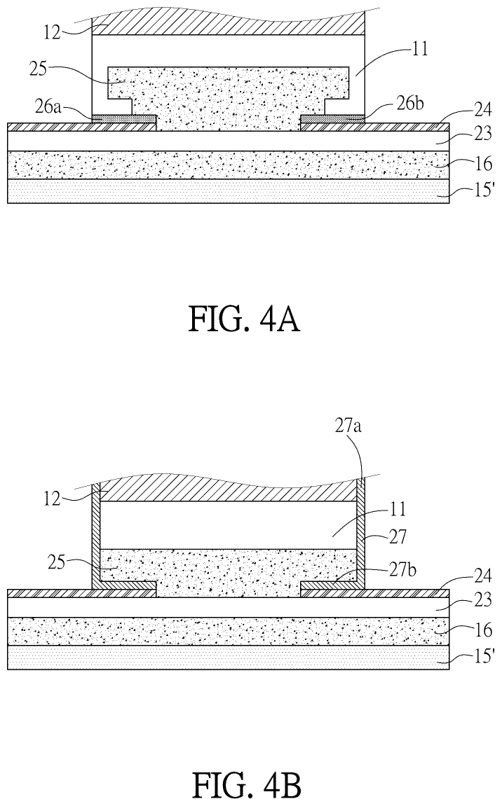

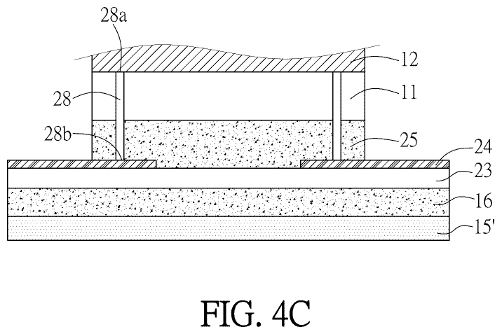

FIGS. 4A to 4C are schematic partial sectional views showing different aspects of the tiled flexible electronic device 10B of this disclosure. In order to make the drawings simpler and clearer, the connection between one tile portion and the base structure is shown, and this tile portion only shows the first flexible layer 11 and the electronic component layer 12, while other layers on the electronic component layer 12 are omitted.

As shown in FIG. 4A, the electronic component layer 12 and the circuit layer 24 can be electrically connected to each other through the flexible circuit elements 26a and 26b. The flexible circuit elements 26a and 26b can be, for example, respectively arranged on the upper surfaces of two side edges of the first flexible layer 11, and electrically connected to the circuit pattern (e.g. including the conductive wires and conductive pads) on the first flexible layer 11. Therefore, the flexible circuit elements 26a and 26b can be respectively electrically connected to the electronic component layer 12 through the circuit pattern on the first flexible layer 11. In addition, the two sides of the first flexible layer 11 can be bent downward, so that the two side edges of the first flexible layer 11 and the flexible circuit elements 26a and 26b can be respectively arranged between the fifth adhesive layer 25 and the circuit layer 24. Accordingly, the flexible circuit elements 26a and 26b can be respectively electrically connected to the circuit layer 24. Therefore, the driving power and/or control signals can be provided to the electronic component layer 12 through the circuit layer 24 and the flexible circuit elements 26a and 26b. In this embodiment, the flexible circuit element 26a can be, for example, a flexible printed circuit (FPC), and the flexible circuit element 26b can be, for example, a COF (chip on film) component, but this disclosure is not limited thereto.

As shown in FIG. 4B, the electronic component layer 12 and the circuit layer 24 can be electrically connected to each other through the side circuits 27. The side circuits 27 are disposed on the sides of the first flexible layer 11 and the electronic component layer 12. One end 27a of the side circuit 27 can be electrically connected to the side circuit of the electronic component layer 12, and the other end 27b of the side circuit 27 extends between the fifth adhesive layer 25 and the circuit layer 24 and is electrically connected to the circuit layer 24. Therefore, control signals and/or driving power can be transmitted to the electronic component layer 12 through the circuit layer 24 and the side circuits 27. In this embodiment, the side circuits 27 are formed, for example, by the same metal layer or different metal layers, and this disclosure is not limited thereto.

As shown in FIG. 4C, the electronic component layer 12 and the circuit layer 24 can be electrically connected to each other through multiple conductive vias 28. The conductive vias 28 are formed in the first flexible layer 11 and the fifth adhesive layer 25 and pass through the first flexible layer 11 and the fifth adhesive layer 25. The conductive vias 28 can be filled with conductive materials, such as metal materials. One end portion 28a of the conductive via 28 is directly electrically connected to the electronic component layer 12, and the other end portion 28b of the conductive via 28 is directly electrically connected to the circuit layer 24. Therefore, the control signals and/or driving power can be transmitted to the electronic component layer 12 through the circuit layer 24 and the conductive vias 28.

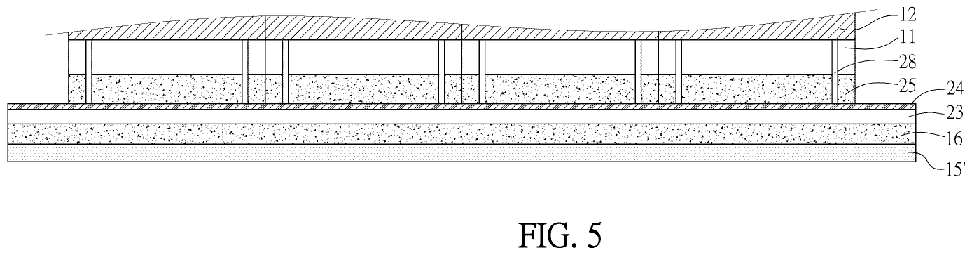

FIG. 5 is a schematic partial sectional view showing a tiled flexible electronic device 10B of this disclosure, wherein the electronic component layer 12 and the circuit layer 24 can be electrically connected to each other through a plurality of conductive vias 28 (see FIG. 4C). A plurality of tile portions are arranged on a large-sized base structure in a tiling manner. To be noted, in order to simplify the drawing, the tile portion as shown in FIG. 5 only shows the first flexible layer 11 and the electronic component layer 12, while the other layers above the electronic component layer 12 are omitted.

In this embodiment, for example, the thickness of the first flexible layer 11 is between 1 μm and 100 μm, the thickness of the anti-reflective layer 14 is between 1 μm and 200 μm, the thickness of the first support layer 15′ is between 25 μm and 300 μm, the thickness of the first adhesive layer 16 is between 1 μm and 500 μm, the thickness of the second adhesive layer 17 is between 1 μm and 100 μm, the thickness of the third adhesive layer 18 is between 1 μm and 50 μm, the thickness of the fourth adhesive layer 21 is between 1 μm and 500 μm, and the thickness of the second support layer 22 is between 25 μm and 300 μm.

As mentioned above, the corresponding relationship between stress and strain of each layer inside the flexible electronic device 10B, when it is bent, for example, to a specified curvature radius Ro, can be simulated and calculated. The organized values are shown in Table 3 below.

TABLE 3

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| 3.703E−6 | −6.334E−6 | 91.2 | 0.666E−3 | −0.657E−3 | 0.009E−3 | 46/54 |

Referring to Table 3, in the flexible electronic device 10B of this embodiment, the maximum stress in the electronic component layer 12 is 3.703E-6 MPa, the maximum stress in the first flexible layer 11 is −6.334E-6 MPa, the neutral axis ratio is 91.2%, the strain value at the upper end surface is 0.666E-3, the strain value at the lower end surface is −0.657E-3, the strain difference is 0.009E-3, and the deviation distance ratio of the electronic component layer 12 is 46/54. In this case, the electronic component layer 12 is close to the center of the neutral axis region but slightly biased toward the lower end surface of the neutral axis region.

The detailed description of other features of the electronic device 10B can refer to the previous embodiment, and will be omitted here.

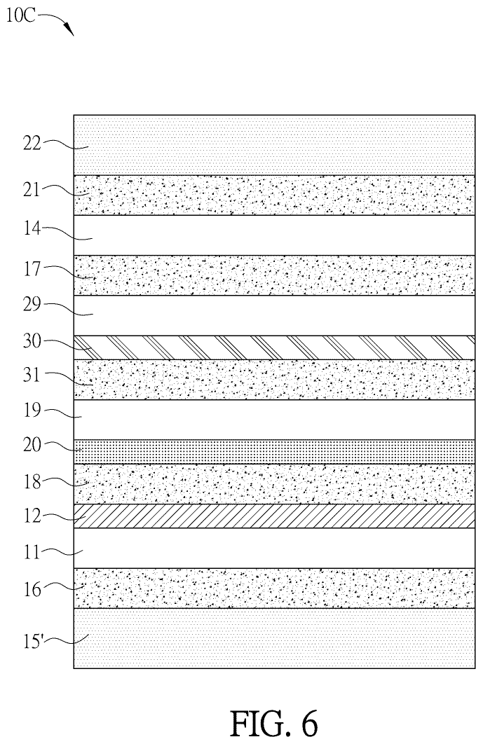

As shown in FIG. 6, compared with the previous embodiment of FIG. 2, the flexible electronic device 10C is not configured with the polarization layer 13, but further includes a fourth adhesive layer 21, a second support layer 22, a fourth flexible layer 29, a sensing layer 30, and a sixth adhesive layer 31. In this embodiment, the second support layer 22 is disposed at one side of the anti-reflective layer 14 away from the second flexible layer 19, and the second support layer 22 can be disposed on the anti-reflective layer 14 through the fourth adhesive layer 21. The fourth flexible layer 29 is disposed between the second flexible layer 19 and the anti-reflective layer 14. The sensing layer 30 is disposed at one side of the fourth flexible layer 29 close to the second flexible layer 19, and the sensing layer 30 can be disposed on the second flexible layer 19 through the sixth adhesive layer 31. In this embodiment, the materials and properties of the fourth adhesive layer 21 and the second support layer 22 can refer to that of the flexible electronic device 10B as shown in FIG. 3, the material and property of the fourth flexible layer 29 can refer to the aforementioned first flexible layer 11, and the material and property of the sixth adhesive layer 31 can refer to the aforementioned first adhesive layer 16, so the detailed descriptions thereof will be omitted here.

In this case, the sensing layer 30 can include, for example, a substrate and a sensing circuit. The sensing circuit may include, for example, a touch sensing circuit layer for providing a touch function, but this disclosure is not limited thereto.

In this embodiment, for example, the thickness of the first flexible layer 11 is between 1 μm and 100 μm, the thickness of the anti-reflective layer 14 is between 1 μm and 200 μm, the thickness of the first support layer 15′ is between 25 μm and 300 μm, the thickness of the first adhesive layer 16 is between 1 μm and 500 μm, the thickness of the second adhesive layer 17 is between 1 μm and 100 μm, the thickness of the third adhesive layer 18 is between 1 μm and 50 μm, the thickness of the fourth adhesive layer 21 is between 1 μm and 500 μm, and the thickness of the second support layer 22 is between 25 μm and 300 am.

As mentioned above, the corresponding relationship between stress and strain of each layer inside the flexible electronic device 10C, when it is bent, for example, to a specified curvature radius Ro, can be simulated and calculated. The organized values are shown in Table 4 below.

TABLE 4

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| 0.925E−3 | 0.940E−3 | 84.9 | 1.449E−3 | −1.574E−3 | 0.125E−3 | 59/41 |

Referring to Table 4, in the flexible electronic device 10C of this embodiment, the maximum stress in the electronic component layer 12 is 0.925E-3 MPa, the maximum stress in the first flexible layer 11 is 0.940E-3 MPa, the neutral axis ratio is 84.9%, the strain value at the upper end surface is 1.449E-3, the strain value at the lower end surface is −1.574E-3, the strain difference is 0.125E-3, and the deviation distance ratio of the electronic component layer 12 is 59/41. In this case, the electronic component layer 12 is close to the center of the neutral axis region but slightly biased toward the upper end surface of the neutral axis region.

The detailed description of other features of the electronic device 10C can refer to the previous embodiment, and will be omitted here.

In the first to fourth embodiments described above, the anti-reflective layers 14 are designed as a single layer of anti-reflective film. Furthermore, the judgements of the product reliabilities (e.g., bending tolerance) of the flexible electronic devices 10, 10A, 10B and 10C can be primarily relied on comparisons of the neutral axis ratios, the strain differences, and the deviation distance ratios of the electronic component layers 12. For example, a higher neutral axis ratio, a lower strain difference, and/or a deviation distance ratio closer to 50/50 indicate a better product reliability. Therefore, by comparing the data in Tables 1 to 4, it can be determined that the flexible electronic device 10B of the third embodiment has a better product reliability.

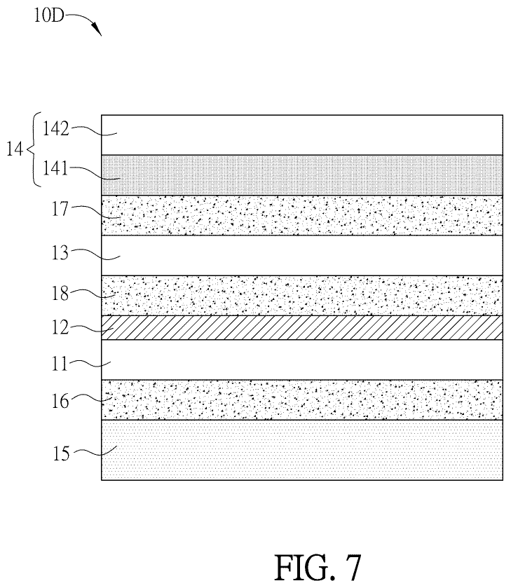

As shown in FIG. 7, compared with the previous embodiment of FIG. 1, in the flexible electronic device 10D, the anti-reflective layer 14 includes a base 141 and an anti-reflective film 142. The base 141 is disposed on the polarization layer 13 through the second adhesive layer 17, and the anti-reflective film 142 is disposed on the base 141. The base 141 may include, for example, ultra-thin glass (UTG), and the anti-reflective film 142 may include, for example, a multilayer structure formed by alternately stacking at least one high refractivity sublayer and at least one low refractivity sublayer. The material of the low refractivity sublayer can be, for example, silicon oxide (SiOx), and the material of the material of the high refractivity sublayer can be, for example, silicon nitride (SiNx), niobium oxide (Nb₂O₅), or the likes. This disclosure is not limited thereto.

In this embodiment, for example, the thickness of the first flexible layer 11 is between 1 μm and 100 μm, the thickness of the anti-reflective layer 14 (the sum of the thicknesses of the base 141 and the anti-reflective film 142) is between 1 μm and 150 μm, the thickness of the support layer 15 is between 25 μm and 300 μm, the thickness of the first adhesive layer 16 is between 1 μm and 500 μm, the thickness of the second adhesive layer 17 is between 1 μm and 500 μm, and the thickness of the third adhesive layer 18 is between 1 μm and 50 μm.

As mentioned above, the corresponding relationship between stress and strain of each layer inside the flexible electronic device 10D, when it is bent, for example, to a specified curvature radius Ro, can be simulated and calculated. The organized values are shown in Table 5 below.

TABLE 5

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| 3.584E−6 | 0.603E−6 | 77.5 | 0.356E−3 | −1.476E−3 | 1.120E−3 | 34/66 |

Referring to Table 5, in the flexible electronic device 10D of this embodiment, the maximum stress in the electronic component layer 12 is 3.584E-6 MPa, the maximum stress in the first flexible layer 11 is 0.603E-6 MPa, the neutral axis ratio is 77.5%, the strain value at the upper end surface is 0.356E-3, the strain value at the lower end surface is −1.476E-3, the strain difference is 1.120E-3, and the deviation distance ratio of the electronic component layer 12 is 34/66. In this case, the electronic component layer 12 is closer to the lower end surface of the neutral axis region.

The detailed description of other features of the electronic device 10D can refer to the previous embodiment, and will be omitted here.

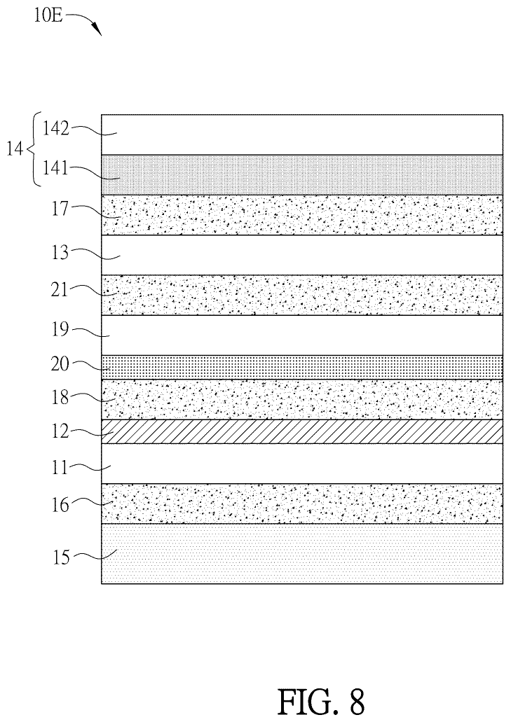

As shown in FIG. 8, compared with the previous embodiment of FIG. 2, in the flexible electronic device 10E, the anti-reflective layer 14 includes a base 141 and an anti-reflective film 142. The base 141 is disposed on the polarization layer 13 through the second adhesive layer 17, and the anti-reflective film 142 is disposed on the base 141. The base 141 may include, for example, UTG, and the anti-reflective film 142 may include, for example, a multilayer structure formed by alternately stacking at least one high refractivity sublayer and at least one low refractivity sublayer. The material of the low refractivity sublayer can be, for example, silicon oxide (SiOx), and the material of the material of the high refractivity sublayer can be, for example, silicon nitride (SiNx), niobium oxide (Nb₂O₅), or the likes. This disclosure is not limited thereto.

In this embodiment, for example, the thickness of the first flexible layer 11 is between 1 μm and 100 μm, the thickness of the anti-reflective layer 14 (the sum of the thicknesses of the base 141 and the anti-reflective film 142) is between 1 μm and 150 μm, the thickness of the support layer 15 is between 25 μm and 300 μm, the thickness of the first adhesive layer 16 is between 1 μm and 500 μm, the thickness of the second adhesive layer 17 is between 1 μm and 500 μm, the thickness of the third adhesive layer 18 is between 1 μm and 50 μm, and the thickness of the fourth adhesive layer 21 is between 1 μm and 500 μm.

As mentioned above, the corresponding relationship between stress and strain of each layer inside the flexible electronic device 10E, when it is bent, for example, to a specified curvature radius Ro, can be simulated and calculated. The organized values are shown in Table 6 below.

TABLE 6

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| −0.009E−4 | −2.907E−4 | 90.9 | 1.009E−3 | −1.612E−3 | 0.603E−3 | 69/31 |

Referring to Table 6, in the flexible electronic device 10E of this embodiment, the maximum stress in the electronic component layer 12 is −0.009E-4 MPa, the maximum stress in the first flexible layer 11 is −2.907E-4 MPa, the neutral axis ratio is 90.9%, the strain value at the upper end surface is 1.009E-3, the strain value at the lower end surface is −1.612E-3, the strain difference is 0.603E-3, and the deviation distance ratio of the electronic component layer 12 is 69/31. In this case, the electronic component layer 12 is closer to the upper end surface of the neutral axis region.

The detailed description of other features of the electronic device 10E can refer to the previous embodiment, and will be omitted here.

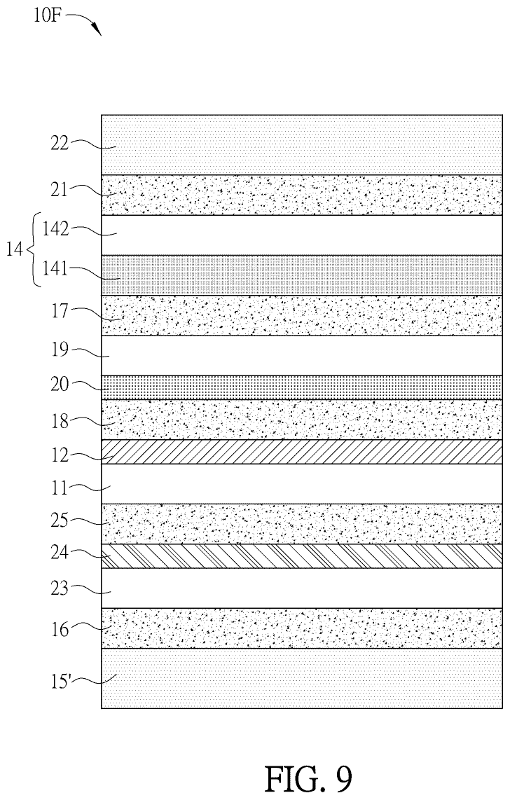

As shown in FIG. 9, compared with the previous embodiment of FIG. 3, in the flexible electronic device 10F, the anti-reflective layer 14 includes a base 141 and an anti-reflective film 142. The base 141 is disposed on the second flexible layer 19 through the second adhesive layer 17, the anti-reflective film 142 is disposed on the base 141, and the second support layer 22 is disposed on the anti-reflective film 142 through the fourth adhesive layer 21. The base 141 may include, for example, UTG, and the anti-reflective film 142 may include, for example, a multilayer structure formed by alternately stacking at least one high refractivity sublayer and at least one low refractivity sublayer. The material of the low refractivity sublayer can be, for example, silicon oxide (SiOx), and the material of the material of the high refractivity sublayer can be, for example, silicon nitride (SiNx), niobium oxide (Nb₂O₅), or the likes. This disclosure is not limited thereto.

In this embodiment, for example, the thickness of the first flexible layer 11 is between 1 μm and 100 μm, the thickness of the anti-reflective layer 14 (the sum of the thicknesses of the base 141 and the anti-reflective film 142) is between 1 μm and 150 μm, the thickness of the first support layer 15′ is between 25 μm and 300 μm, the thickness of the first adhesive layer 16 is between 1 μm and 500 μm, the thickness of the second adhesive layer 17 is between 1 μm and 500 μm, the thickness of the third adhesive layer 18 is between 1 μm and 50 μm, the thickness of the fourth adhesive layer 21 is between 1 μm and 500 μm, and the thickness of the second supporting layer 22 is between 25 μm and 300 μm.

As mentioned above, the corresponding relationship between stress and strain of each layer inside the flexible electronic device 10F, when it is bent, for example, to a specified curvature radius Ro, can be simulated and calculated. The organized values are shown in Table 7 below.

TABLE 7

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| −4.396E−6 | 1.706E−6 | 90.9 | 0.658E−3 | −0.650E−3 | 0.008E−3 | 43/57 |

Referring to Table 7, in the flexible electronic device 10F of this embodiment, the maximum stress in the electronic component layer 12 is −4.396E-6 MPa, the maximum stress in the first flexible layer 11 is 1.706E-6 MPa, the neutral axis ratio is 90.9%, the strain value at the upper end surface is 0.658E-3, the strain value at the lower end surface is −0.650E-3, the strain difference is 0.008E-3, and the deviation distance ratio of the electronic component layer 12 is 43/57. In this case, the electronic component layer 12 is close to the center of the neutral axis region but slightly biased toward the lower end surface of the neutral axis region.

The detailed description of other features of the electronic device 10F can refer to the previous embodiment, and will be omitted here.

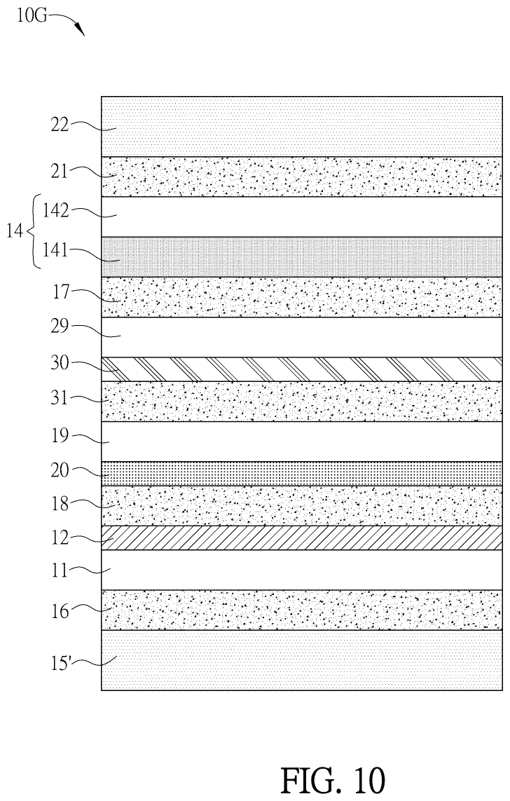

As shown in FIG. 10, compared with the previous embodiment of FIG. 6, in the flexible electronic device 10G, the anti-reflective layer 14 includes a base 141 and an anti-reflective film 142. The base 141 is disposed on the fourth flexible layer 29 through the second adhesive layer 17, the anti-reflective film 142 is disposed on the base 141, and the second support layer 22 is disposed on the anti-reflective film 142 through the fourth adhesive layer 21. The base 141 may include, for example, UTG, and the anti-reflective film 142 may include, for example, a multilayer structure formed by alternately stacking at least one high refractivity sublayer and at least one low refractivity sublayer. The material of the low refractivity sublayer can be, for example, silicon oxide (SiOx), and the material of the material of the high refractivity sublayer can be, for example, silicon nitride (SiNx), niobium oxide (Nb₂O₅), or the likes. This disclosure is not limited thereto.

In this embodiment, for example, the thickness of the first flexible layer 11 is between 1 μm and 100 μm, the thickness of the anti-reflective layer 14 (the sum of the thicknesses of the base 141 and the anti-reflective film 142) is between 1 μm and 150 μm, the thickness of the first support layer 15′ is between 25 μm and 300 μm, the thickness of the first adhesive layer 16 is between 1 μm and 500 μm, the thickness of the second adhesive layer 17 is between 1 μm and 500 μm, the thickness of the third adhesive layer 18 is between 1 μm and 50 μm, the thickness of the fourth adhesive layer 21 is between 1 μm and 500 μm, and the thickness of the second support layer 22 is between 25 μm and 300 μm.

As mentioned above, the corresponding relationship between stress and strain of each layer inside the flexible electronic device 10G, when it is bent, for example, to a specified curvature radius Ro, can be simulated and calculated. The organized values are shown in Table 8 below.

TABLE 8

| | | | | | | Deviation |
|---|---|---|---|---|---|---|
| Maximum stress (MPa) | | Neutral | Strain value of end surface | | | distance ratio |
| Electronic | First | axis | Upper | Lower | | of electronic |
| component | flexible | ratio | end | end | Strain | component |
| layer | layer | (%) | surface | surface | difference | layer |
| 3.550E−3 | −7.023E−3 | 83.0 | 1.735E−3 | −1.685E−3 | 0.050E−3 | 62/38 |

Referring to Table 8, in the flexible electronic device 10G of this embodiment, the maximum stress in the electronic component layer 12 is 3.550E-3 MPa, the maximum stress in the first flexible layer 11 is −7.023E-3 MPa, the neutral axis ratio is 83.0%, the strain value at the upper end surface is 1.735E-3, the strain value at the lower end surface is −1.685E-3, the strain difference is 0.050E-3, and the deviation distance ratio of the electronic component layer 12 is 62/38. In this case, the electronic component layer 12 is close to the center of the neutral axis region but slightly biased toward the upper end surface of the neutral axis region.

The detailed description of other features of the electronic device 10G can refer to the previous embodiment, and will be omitted here.

In the fifth to eighth embodiments described above, each of the anti-reflective layers 14 includes a base 141 and an anti-reflective film 142. Furthermore, the judgement of the product reliabilities (e.g., bending tolerance) of the flexible electronic devices 10D, 10E, 10F and 10G can be primarily relied on comparisons of the neutral axis ratios, the strain differences, and the deviation distance ratios of the electronic component layers 12. For example, a higher neutral axis ratio, a lower strain difference, and/or a deviation distance ratio closer to 50/50 indicate a better product reliability. Therefore, by comparing the data in Tables 5 to 8, it can be determined that the flexible electronic device 10F of the seventh embodiment has a better product reliability.

In summary, the flexible electronic device of embodiments of this disclosure has a stacked structure including a support layer, a first flexible layer, an electronic component layer, a polarization layer, and an anti-reflective layer. These layers are stacked sequentially from bottom to top, wherein the first adhesive layer is disposed between the first flexible layer and the support layer, and the second adhesive layer is disposed between the anti-reflective layer and the polarization layer. The thickness of the first adhesive layer is greater than that of the second adhesive layer. In other embodiments, the flexible electronic device has a stacked structure including a first support layer, a first flexible layer, an electronic component layer, a color filter layer, a second flexible layer, an anti-reflective layer, and a second support layer. These layers are stacked sequentially from bottom to top, wherein the first adhesive layer is disposed between the first support layer and the first flexible layer, and the second adhesive layer is disposed between the anti-reflective layer and the second flexible layer. The thickness of the first adhesive layer is greater than that of the second adhesive layer. As mentioned above, this disclosure can reduce the reflectivity of the flexible electronic device by configuring the anti-reflective layer and coordinating the thickness design of the first adhesive layer and the second adhesive layer, thereby improving the ambient contrast ratio and ensuring the structural flexibility and/or reliability of the structure.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A flexible electronic device, comprising:
a first flexible layer;
an electronic component layer disposed on the first flexible layer;
a polarization layer disposed at one side of the electronic component layer away from the first flexible layer;
an anti-reflective layer disposed at one side of the polarization layer away from the electronic component layer;
a support layer disposed at one side of the first flexible layer away from the electronic component layer;
a first adhesive layer disposed between the first flexible layer and the support layer; and
a second adhesive layer disposed between the anti-reflective layer and the polarization layer;
wherein, a thickness of the first adhesive layer is greater than a thickness of the second adhesive layer.

2. The flexible electronic device of claim 1, further comprising:
a second flexible layer disposed between the polarization layer and the electronic component layer; and
a color filter layer disposed between the second flexible layer and the electronic component layer.

3. The flexible electronic device of claim 2, further comprising:
a third adhesive layer disposed between the color filter layer and the electronic component layer, wherein the thickness of the first adhesive layer is greater than a thickness of the third adhesive layer.

4. The flexible electronic device of claim 2, wherein with respect to visible light, a transparency of the second flexible layer is greater than a transparency of the first flexible layer.

5. The flexible electronic device of claim 1, wherein a thickness of the support layer is greater than a thickness of the first flexible layer.

6. The flexible electronic device of claim 1, wherein the electronic component layer comprises a plurality of micro LEDs.

7. The flexible electronic device of claim 1, wherein the anti-reflective layer comprises a base and an anti-reflective film, and the anti-reflective film is disposed on the base.

8. A flexible electronic device, comprising:
a first flexible layer;
a second flexible layer disposed opposite to the first flexible layer;
an electronic component layer disposed between the first flexible layer and the second flexible layer;
a color filter layer disposed between the second flexible layer and the electronic component layer;
an anti-reflective layer disposed at one side of the second flexible layer away from the first flexible layer;
a first support layer disposed at one side of the first flexible layer away from the second flexible layer;
a second support layer disposed at one side of the anti-reflective layer away from the second flexible layer;
a first adhesive layer disposed between the first support layer and the first flexible layer; and
a second adhesive layer disposed between the anti-reflective layer and the second flexible layer;
wherein, a thickness of the first adhesive layer is greater than a thickness of the second adhesive layer.

9. The flexible electronic device of claim 8, further comprising:
a third adhesive layer disposed between the color filter layer and the electronic component layer, wherein the thickness of the first adhesive layer is greater than a thickness of the third adhesive layer.

10. The flexible electronic device of claim 8, wherein with respect to visible light, a transparency of the second flexible layer is greater than a transparency of the first flexible layer.

11. The flexible electronic device of claim 8, further comprising:
a third flexible layer disposed between the first flexible layer and the first support layer; and
a circuit layer disposed at one side of the third flexible layer close to the first flexible layer, wherein the electronic component layer is electrically connected to the circuit layer.

12. The flexible electronic device of claim 8, further comprising:
a fourth flexible layer disposed between the second flexible layer and the anti-reflective layer; and
a sensing layer disposed at one side of the fourth flexible layer close to the second flexible layer.

13. The flexible electronic device of claim 8, wherein the electronic component layer comprises a plurality of micro LEDs.

14. The flexible electronic device of claim 8, wherein the anti-reflective layer comprises a base and an anti-reflective film, and the anti-reflective film is disposed on the base.

15. A flexible electronic device, comprising:
a first support layer;
a first adhesive layer;
a plurality of tile portions, wherein the tile portions are tiled and disposed on the first support layer through the first adhesive layer, and each of the tile portions comprises:
a first flexible layer, wherein the first support layer is disposed at one side of the first flexible layer, and the first adhesive layer is disposed between the first support layer and the first flexible layer,
a second flexible layer disposed opposite to the first flexible layer,
an electronic component layer disposed between the first flexible layer and the second flexible layer,
a color filter layer disposed between the second flexible layer and the electronic component layer,
an anti-reflective layer disposed at one side of the second flexible layer away from the first flexible layer,
a second support layer disposed at one side of the anti-reflective layer away from the second flexible layer, and
a second adhesive layer disposed between the anti-reflective layer and the second flexible layer, wherein a thickness of the first adhesive layer is greater than a thickness of the second adhesive layer.

16. The flexible electronic device of claim 15, further comprising:
a third adhesive layer disposed between the color filter layer and the electronic component layer, wherein the thickness of the first adhesive layer is greater than a thickness of the third adhesive layer.

17. The flexible electronic device of claim 15, wherein with respect to visible light, a transparency of the second flexible layer is greater than a transparency of the first flexible layers.

18. The flexible electronic device of claim 15, further comprising:
a third flexible layer disposed between the first support layer and the first flexible layers of the tile portions; and
a circuit layer disposed at one side of the third flexible layer close to the first flexible layers, wherein the electronic component layers of the tile portions are electrically connected to the circuit layer.

19. The flexible electronic device of claim 15, wherein each of the electronic component layers comprises a plurality of micro LEDs.

20. The flexible electronic device of claim 15, wherein the anti-reflective layer comprises a base and an anti-reflective film, and the anti-reflective film is disposed on the base.
